(19) United States
(12) Patent Application Publication
(10) Pub. No.: US 2025/0024739 A1
(43) Pub. Date: Jan. 16, 2025

(54) DISPLAY DEVICE

(71) Applicant: Samsung Display Co., LTD., Yongin-si (KR)

(72) Inventor: Ho LIM, Yongin-si (KR)

(21) Appl. No.: 18/423,515

(22) Filed: Jan. 26, 2024

(30) Foreign Application Priority Data
Jul. 10, 2023 (KR) 10-2023-0089311

(51) Int. Cl. H10K 59/80; H10K 59/38; H10K 102/00

(52) U.S. Cl. CPC H10K 59/879; H10K 59/38; H10K 59/87; H10K 2102/351

(57) ABSTRACT

A display device includes: a display layer; an overcoat layer disposed on the display layer and including an organic material; and an anti-reflection layer disposed on the overcoat layer. The anti-reflection layer includes: a first passivation layer; a first refractive layer disposed on the first passivation layer and having a first refractive index; a second refractive layer disposed on the first refractive layer and having a second refractive index; a second passivation layer disposed on the second refractive layer; and an outer refractive layer disposed on the second passivation layer and having an outer refractive index. The first passivation layer and the second passivation layer include an oxide. The first refractive index is less than the second refractive index, and the outer refractive index is less than the first refractive index.

The application claims priority to Korean patent application No. 10-2023-0089311 under 35 U.S.C. § 119, filed on Jul. 10, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

As information technology develops, importance of a display device, which is a communication medium between a user and information, is being highlighted.

It is desirable for the display device to have a structure for improving external visibility. For example, a desirability for adjusting external light reflectance for improving external visibility exists.

### SUMMARY

An aspect of the disclosure is to provide a display device having improved visibility by controlling external light reflectance.

An aspect of the disclosure is to provide a display device in which reliability of display quality is reconsidered.

According to an embodiment of the disclosure, a display device includes: a display layer, an overcoat layer disposed on the display layer and including an organic material, and an anti-reflection layer disposed on the overcoat layer. The anti-reflection layer includes a first passivation layer, a first refractive layer disposed on the first passivation layer and having a first refractive index, a second refractive layer disposed on the first refractive layer and having a second refractive index, a second passivation layer disposed on the second refractive layer, and an outer refractive layer disposed on the second passivation layer and having an outer refractive index. The first passivation layer and the second passivation layer include an oxide. The first refractive index is less than the second refractive index, and the outer refractive index is less than the first refractive index.

According to an embodiment, one surface of the first passivation layer may contact the overcoat layer, and another surface of the first passivation layer may contact the first refractive layer. One surface of the second passivation layer may contact the second refractive layer, and another surface of the second passivation layer may contact the outer refractive layer.

According to an embodiment, an outer surface of the outer refractive layer may be exposed to the outside so that the outer refractive layer forms an outermost structure of the display device.

According to an embodiment, the first refractive layer may include silicon oxynitride (SiOxNy). The second refractive layer may include silicon nitride (SiNx).

According to an embodiment, the outer refractive layer may include one or more among silica, an organic material at least partially substituted with a fluorine group, an inorganic material at least partially substituted with a fluorine group, and an organic/inorganic hybrid material at least partially substituted with a fluorine group.

According to an embodiment, the first passivation layer and the second passivation layer may include silicon oxide (SiOx).

According to an embodiment, the first refractive index may be in a range of 1.60 to 1.69. The second refractive index may be in a range of 1.70 to 2.10. The outer refractive index may be in a range of 1.23 to 1.40.

According to an embodiment, a thickness of the second passivation may be less than a thickness of each of the first refractive layer, the second refractive layer, the first passivation layer, and the outer refractive layer.

According to an embodiment, the first refractive layer may have the thickness in a range of 50 nanometers (nm) to 150 nm. The second refractive layer may have the thickness in a range of 50 nm to 150 nm. The first passivation layer may have the thickness in a range of from 200 nm to 300 nm. The outer refractive layer may have the thickness in a range of 50 nm to 150 nm. The second passivation layer may have the thickness in a range of 20 nm to 50 nm.

According to an embodiment, when external light is applied to the display device, at least a portion of the external light may be reflected at an outer surface of the outer refractive layer or at an interface between the second passivation layer and the second refractive layer, and may be provided as first reflected light of which a phase is inverted with respect to a phase of the at least a portion of the external light, and at least another portion of the external light may be reflected at an interface between the first refractive layer and the second refractive layer or at an interface between the first passivation layer and the first refractive layer and may be provided as second reflected light of which a phase is maintained with respect to a phase of the at least another portion of the external light.

According to an embodiment, at least a portion of the first reflected light and at least a portion of the second reflected light may dissipate by destructive interference with each other.

According to an embodiment, the display device may further include a plurality of sub-pixels forming sub-pixel areas, respectively. The anti-reflection layer may include an inorganic material so as to be formed by a deposition process and may be disposed over the sub-pixel areas.

According to an embodiment, the overcoat layer and the first passivation layer may be combined with each other without an adhesive layer interposed therebetween.

According to an embodiment, the display device may further include a color conversion layer disposed on the display layer and including a quantum-dot, and a color filter layer disposed on the color conversion layer and configured to selectively transmit light of one color.

According to an embodiment, the display layer may include an organic light emitting diode (“OLED”).

According to an embodiment, the overcoat layer may form a base on which the anti-reflection layer is disposed so that a substrate is not disposed on the anti-reflection layer.

According to an embodiment, the overcoat layer may have a thickness in a range of 3 micrometers (μm) to 10 μm.

According to an embodiment of the disclosure, a display device includes: a display layer, an overcoat layer disposed on the display layer and including an organic material, and an anti-reflection layer disposed on the overcoat layer. The anti-reflection layer includes a first passivation layer, a third refractive layer disposed on the first passivation layer and having a third refractive index, a first refractive layer disposed on the third refractive layer and having a first refractive index, a second refractive layer disposed on the first refractive layer and having a second refractive index, a second passivation layer disposed on the second refractive layer, and an outer refractive layer disposed on the second passivation layer and having an outer refractive index. The first passivation layer, the second passivation layer, and the first refractive layer include an oxide. The second refractive layer and the third refractive layer include the same material. Each of the second refractive index and the third refractive index are greater than the first refractive index, and the outer refractive index is less than the first refractive index.

According to an embodiment, the first passivation layer and the second passivation layer may include silicon oxide (SiOx). The first refractive layer may include silicon oxide (SiOx). The second refractive layer and the third refractive layer may include silicon nitride (SiNx).

According to an embodiment, the first refractive index may be in a range of 1.60 to 1.69. The second refractive index and the third refractive index may each be in a range of 1.70 to 2.10.

According to an embodiment of the disclosure, a display device having improved visibility by controlling external light reflectance may be provided.

According to an embodiment of the disclosure, a display device in which reliability of display quality is reconsidered may be provided.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIG. 2 is a schematic cross-sectional view illustrating a display device according to an embodiment;

FIGS. 3 and 4 are schematic cross-sectional views illustrating an anti-reflection layer according to an embodiment;

FIGS. 5 and 6 are schematic cross-sectional views illustrating an anti-reflection layer according to an embodiment; and

FIGS. 7 and 8 are schematic cross-sectional views illustrating an anti-reflection layer according to an embodiment.

### DETAILED DESCRIPTION

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The disclosure relates to a display device. Hereinafter, a display device according to an embodiment is described with reference to the accompanying drawings.

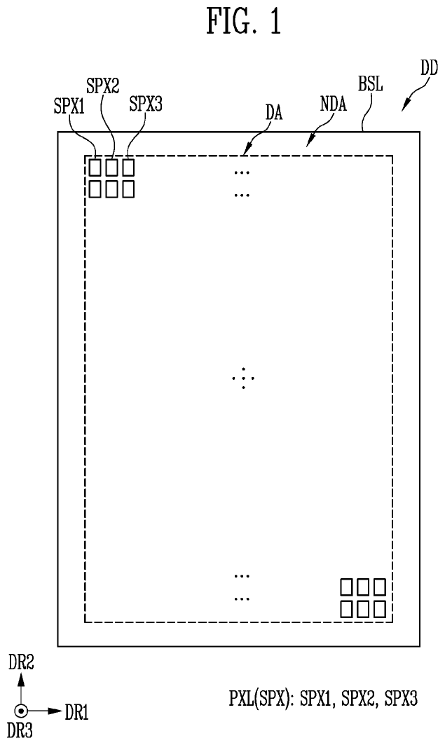

FIG. 1 is a schematic plan view illustrating a display device according to an embodiment.

Referring to FIG. 1, the display device DD may include a base layer BSL and a pixel PXL disposed on the base layer BSL. Although not shown in the drawing, the display device DD may further include a driving circuit unit (for example, a scan driver and a data driver), lines, and pads for driving the pixel PXL.

The display device DD (or the base layer BSL) may include a display area DA and a non-display area NDA. The non-display area NDA may mean an area other than the display area DA. The non-display area NDA may surround at least a portion of the display area DA.

The base layer BSL may form a base surface of the display device DD. The base layer BSL may be a rigid or flexible substrate or film. For example, the base layer BSL may be a rigid substrate formed of glass or tempered glass, a flexible substrate (or thin film) of a plastic or metal material, or at least one insulating layer. A material and/or a physical property of the base layer BSL are/is not particularly limited. In an embodiment, the base layer BSL may be substantially transparent. Here, “substantially transparent” may mean that light is transmitted at a level of a predetermined transmittance or more (e.g., 90%, 95%, 97%, etc.). In another embodiment, the base layer BSL may be translucent or opaque. In addition, the base layer BSL may include a reflective material according to an embodiment.

The display area DA may mean an area where the pixel PXL is disposed. The non-display area NDA may mean an area where the pixel PXL is not disposed. The driving circuit unit, the line, and the pads connected to the pixel PXL of the display area DA may be disposed in the non-display area NDA.

According to an embodiment, the pixel PXL (or sub-pixels SPX) may be arranged according to a stripe or PENTILE™ arrangement structure, but are not limited thereto, and various embodiments may be applied to the disclosure.

According to an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form one pixel unit capable of emitting light of various colors.

For example, each of the first sub-pixel SPX1, the second sub-pixel SPX2, and the third sub-pixel SPX3 may emit light of one color. For example, the first sub-pixel SPX1 may be a red pixel emitting light of red (for example, first color), the second sub-pixel SPX2 may be a green pixel emitting light of green (for example, second color), and the third sub-pixel SPX3 may be a blue pixel emitting light of blue (for example, third color). According to an embodiment, the number of second sub-pixels SPX2 may be greater than each of the number of first sub-pixels SPX1 and the number of third sub-pixels SPX3. However, the color, type, number, and/or the like of the first sub-pixel SPX1, the second sub-pixel SPX2, and the third sub-pixel SPX3 forming each pixel unit are/is not limited to a specific example.

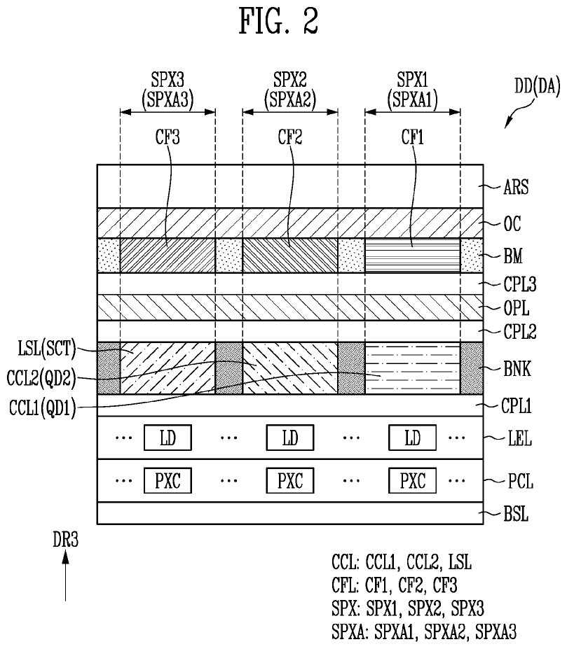

FIG. 2 is a schematic cross-sectional view illustrating a display device according to an embodiment.

Referring to FIG. 2, the display device DD according to an embodiment may include the base layer BSL, a pixel-circuit layer PCL, and a light-emitting-element layer LEL. FIG. 2 shows a cross-sectional structure of the display device DD in the display area DA.

The base layer BSL may form a base on which the pixel-circuit layer PCL and the light-emitting-element layer LEL are disposed. According to an embodiment, the base layer BSL may be a glass substrate.

The pixel-circuit layer PCL may be disposed on the base layer BSL. The pixel-circuit layer PCL may be a layer including a pixel circuit PXC for driving light emitting elements LD. The pixel-circuit layer PCL may include the base layer BSL, conductive layers for forming pixel circuits, and insulating layers disposed on the conductive layers.

The light-emitting-element layer LEL may be disposed on the pixel-circuit layer PCL. According to an embodiment, the light-emitting-element layer LEL may include the light emitting element LD. The light emitting element LD may be an inorganic light emitting diode including an inorganic semiconductor, and the light emitting element LD may be an organic light emitting diode (OLED) including an organic material. However, the disclosure is not limited to a specific example. According to an embodiment, the light-emitting-element layer LEL may be referred to as a display layer.

The light emitting element LD may be electrically connected to the pixel circuit PXC. The light emitting element LD may emit light based on an electrical signal (for example, current intensity) provided from the pixel circuit PXC.

According to an embodiment, light emitted from the light emitting element LD may pass through one or more layers and may be emitted to the outside of the display device DD. For example, the display device DD may include a color conversion layer CCL, a color filter layer CFL, and an anti-reflection layer ARS through which light may pass.

According to an embodiment, sub-pixel areas SPXA corresponding to the sub-pixels SPX, respectively, may be formed in the display area DA. The sub-pixel areas SPXA may include a first sub-pixel area SPXA1 corresponding to the first sub-pixel SPX1, a second sub-pixel area SPXA2 corresponding to the second sub-pixel SPX2, and a third sub-pixel area SPXA3 corresponding to the third sub-pixel SPX3.

According to an embodiment, a first capping layer CPL1 may be disposed on the light-emitting-element layer LEL. The first capping layer CPL1 may be provided over the first to third sub-pixels SPX1, SPX2, and SPX3. The first capping layer CPL1 may cover the light-emitting-element layer LEL. According to an embodiment, the first capping layer CPL1 may be an inorganic layer and may include at least one of a group of silicon nitride (SiNx), aluminum nitride (AlNx), titanium nitride (TiNx), silicon oxide (SiOx), aluminum oxide (AlxOy), titanium oxide (TiOx), silicon oxycarbide (SiOxCy), and silicon oxynitride (SiOxNy).

According to an embodiment, a bank BNK and the color conversion layer CCL may be disposed on the first capping layer CPL1.

According to an embodiment, the bank BNK may be disposed between or at a boundary between the first to third sub-pixel areas SPXA1, SPXA2, and SPXA3, and may define a space (or an area) overlapping the first to third sub-pixel areas SPXA1, SPXA2, and SPXA3, respectively. The space defined by the bank BNK may be an area where the color conversion layer CCL may be provided. According to an embodiment, the bank BNK may include an organic material. The organic material may include at least one of a group of acrylic resin, epoxy resin, phenol resin, polyamide resin, polyimide resin, polyester resin, polyphenylenesulfide resin, and benzocyclobutene. However, the disclosure is not necessarily limited thereto.

According to an embodiment, the color conversion layer CCL may be disposed in a space surrounded by the bank BNK. The color conversion layer CCL may include a first color conversion layer CCL1 disposed in the first sub-pixel SPX1, a second color conversion layer CCL2 disposed in the second sub-pixel SPX2, and a scattering layer LSL disposed in the third sub-pixel SPX3.

The color conversion layer CCL may be disposed on the light emitting element LD. The color conversion layer CCL may be configured to change a wavelength of light. According to an embodiment, the first to third sub-pixels SPX1, SPX2, and SPX3 may include light emitting elements LD emitting light of the same color as each other. For example, the first to third sub-pixels SPX1, SPX2, and SPX3 may include light emitting elements LD emitting light of the third color (or blue). As the color conversion layer CCL including color conversion particles is disposed on each of the first to third sub-pixels SPX1, SPX2, and SPX3, a full color image may be displayed.

However, the color of the light emitted from the light emitting element LD is not limited to the above-described example. For convenience of description, the disclosure is described based on an embodiment in which the light emitting element LD of each of the sub-pixels SPX emits blue light.

The first color conversion layer CCL1 may include first color conversion particles that convert the light of the third color emitted from the light emitting element LD into the light of the first color. For example, the first color conversion layer CCL1 may include a plurality of first quantum dots QD1 dispersed in one matrix material such as a base resin.

According to an embodiment, when the light emitting element LD is a blue light emitting element emitting blue light and the first sub-pixel SPX1 is a red pixel, the first color conversion layer CCL1 may include a first quantum dot QD1 converting the blue light emitted from the blue light emitting element into red light. The first quantum dot QD1 may absorb the blue light and emit the red light by shifting a wavelength according to an energy transition. When the first sub-pixel SPX1 is a pixel of another color, the first color conversion layer CCL1 may include a first quantum dot QD1 corresponding to the color of the first sub-pixel SPX1.

The second color conversion layer CCL2 may include second color conversion particles that convert the light of the third color emitted from the light emitting element LD into the light of the second color. For example, the second color conversion layer CCL2 may include a plurality of second quantum dots QD2 dispersed in one matrix material such as a base resin.

According to an embodiment, when the light emitting element LD is the blue light emitting element emitting the blue light and the second sub-pixel SPX2 is a green pixel, the second color conversion layer CCL2 may include a second quantum dot QD2 converting the blue light emitted from the blue light emitting element into green light. The second quantum dot QD2 may absorb the blue light and emit the green light by shifting a wavelength according to an energy transition. When the second sub-pixel SPX2 is a pixel of another color, the second color conversion layer CCL2 may include a second quantum dot QD2 corresponding to the color of the second sub-pixel SPX2.

According to an embodiment, as the blue light having a relatively short wavelength in a visible ray area is incident to each of the first quantum dot QD1 and the second quantum dot QD2, an absorption coefficient of the first quantum dot QD1 and the second quantum dot QD2 may be increased. Accordingly, finally, efficiency of light emitted from the first sub-pixel SPX1 and the second sub-pixel SPX2 may be improved and excellent color reproducibility may be secured. In addition, since the first to third sub-pixels SPX1, SPX2, and SPX3 are formed by using the light emitting elements LD of the same color (for example, the blue light emitting element), manufacturing efficiency of the display device DD may be increased.

The scattering layer LSL may be provided to efficiently use the light of the third color (or blue) emitted from the light emitting element LD. For example, when the light emitting element LD is the blue light emitting element emitting the blue light and the third sub-pixel SPX3 is a blue pixel, the scattering layer LSL may include at least one type of scattering body SCT in order to efficiently use the light emitted from the light emitting element LD. For example, the scattering body SCT of the scattering layer LSL may include various light scattering particles or light scattering materials. For example, the scattering body may include one or more of a group of silica (SiOx) (for example, silica bead, hollow silica, and the like), titanium oxide (TiOx), zirconium oxide (ZrOx), aluminum oxide (AlxOy), indium oxide (InxOy), zinc oxide (ZnOx), tin oxide (SnOx), and antimony oxide (SbxOy). However, the disclosure is not limited thereto.

The scattering body SCT may be disposed outside the third sub-pixel SPX3, and may be selectively included in the first color conversion layer CCL1 or the second color conversion layer CCL2. According to an embodiment, the scattering body SCT may be omitted, and thus the scattering layer LSL including a transparent polymer may be provided.

A second capping layer CPL2 may be disposed on the color conversion layer CCL and the bank BNK. The second capping layer CPL2 may be provided over the first to third sub-pixels SPX1, SPX2, and SPX3. The second capping layer CPL2 may cover the color conversion layer CCL. According to an embodiment, the second capping layer CPL2 may be an inorganic layer, and may include one or more of a group of silicon nitride (SiNx), aluminum nitride (AlNx), titanium nitride (TiNx), silicon oxide (SiOx), aluminum oxide (AlxOy), titanium oxide (TiOx), silicon oxycarbide (SiOxCy), and silicon oxynitride (SiOxNy).

An optical layer OPL may be disposed on the second capping layer CPL2. The optical layer OPL may serve to improve light extraction efficiency by recycling light provided from the color conversion layer CCL by total reflection. To this end, the optical layer OPL may have a relatively low refractive index compared to the color conversion layer CCL. For example, a refractive index of the color conversion layer CCL may be about 1.6 to 2.0, and a refractive index of the optical layer OPL may be about 1.1 to 1.3.

A third capping layer CPL3 may be disposed on the optical layer OPL. The third capping layer CPL3 may be provided over the first to third sub-pixels SPX1, SPX2 and SPX3. The third capping layer CPL3 may cover the optical layer OPL. According to an embodiment, the third capping layer CPL3 may be an inorganic layer, and may include one or more of a group of silicon nitride (SiNx), aluminum nitride (AlNx), titanium nitride (TiNx), silicon oxide (SiOx), aluminum oxide (AlxOy), titanium oxide (TiOx), silicon oxycarbide (SiOxCy), and silicon oxynitride (SiOxNy).

A light blocking layer BM and the color filter layer CFL may be disposed on the third capping layer CPL3. The color filter layer CFL may include color filters CF1, CF2, and CF3 corresponding to the color of the sub-pixels SPX. Since the color filters CF1, CF2, and CF3 corresponding to the colors of the first to third sub-pixels SPX1, SPX2, and SPX3, respectively, are disposed, a full color image may be displayed.

The color filter layer CFL may include a first color filter CF1 disposed in the first sub-pixel SPX1 to selectively transmit light emitted from the first sub-pixel SPX1, a second color filter CF2 disposed in the second sub-pixel SPX2 to selectively transmit light emitted from the second sub-pixel SPX2, and a third color filter CF3 disposed in the third sub-pixel SPX3 to selectively transmit light emitted from the third sub-pixel SPX3.

The first color filter CF1 may overlap the first color conversion layer CCL1 in the thickness direction (for example, the third direction DR3) of the base layer BSL. The first color filter CF1 may include a color filter material that selectively transmits the light of the first color (or red). For example, when the first sub-pixel SPX1 is a red pixel, the first color filter CF1 may include a red color filter material.

The second color filter CF2 may overlap the second color conversion layer CCL2 in the thickness direction (for example, the third direction DR3) of the base layer BSL. The second color filter CF2 may include a color filter material that selectively transmits the light of the second color (or green). For example, when the second sub-pixel SPX2 is a green pixel, the second color filter CF2 may include a green color filter material.

The third color filter CF3 may overlap the scattering layer LSL in the thickness direction (for example, the third direction DR3) of the base layer BSL. The third color filter CF3 may include a color filter material that selectively transmits the light of the third color (or blue). For example, when the third sub-pixel SPX3 is a blue pixel, the third color filter CF3 may include a blue color filter material.

According to an embodiment, the light blocking layer BM may be disposed between the sub-pixel areas SPXA. The light blocking layer BM may prevent a color mixing defect viewed from a front surface or a side surface of the display device DD. A material of the light blocking layer BM is not particularly limited and may be formed of various light blocking materials. For example, the light blocking layer BM may include a black matrix, or the first to third color filters CF1, CF2, and CF3 may be stacked on each other to implement the light blocking layer BM.

An overcoat layer OC may be disposed on the color filter layer CFL. The overcoat layer OC may be provided over the first to third sub-pixels SPX1, SPX2, and SPX3. The overcoat layer OC may cover a lower member including the color filter layer CFL. The overcoat layer OC may prevent permeation of moisture or air into the above-described lower member. In addition, the overcoat layer OC may protect the above-described lower member from a foreign substance such as dust.

According to an embodiment, the overcoat layer OC may have a robust characteristic (for example, high hardness). Accordingly, a robust characteristic required for the display device DD may be implemented without requiring an additional structure (for example, an upper substrate or the like), and a base on which the anti-reflection layer ARS may be disposed may be formed.

According to an embodiment, the overcoat layer OC may have a thickness greater than a thickness of the anti-reflection layer ARS. For example, the overcoat layer OC may have a thickness in a range of 3 micrometers (μm) to 10 μm. However, the disclosure is not limited thereto.

According to an embodiment, the overcoat layer OC may have a refractive index less than a refractive index of a refractive layer L. The overcoat layer OC may have a refractive index greater than a refractive index of an outer refractive index nL of an outer refractive layer LL. For example, the overcoat layer OC may have a refractive index in a range of 1.45 to 1.53. However, the disclosure is not limited thereto.

According to an embodiment, the overcoat layer OC may include various materials having the robust characteristic.

For example, the overcoat layer OC may include one or more of compounds expressed by Chemical Formulas 1 to 14 below:

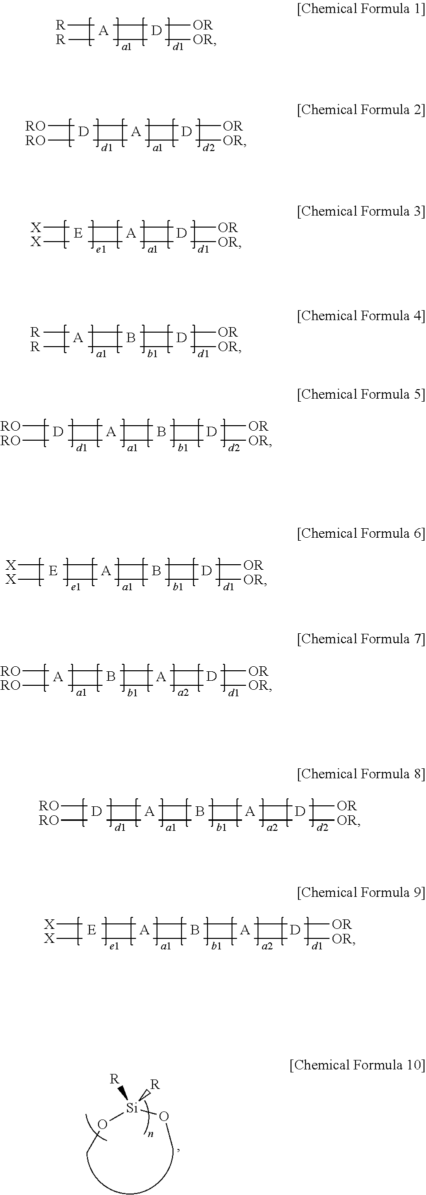

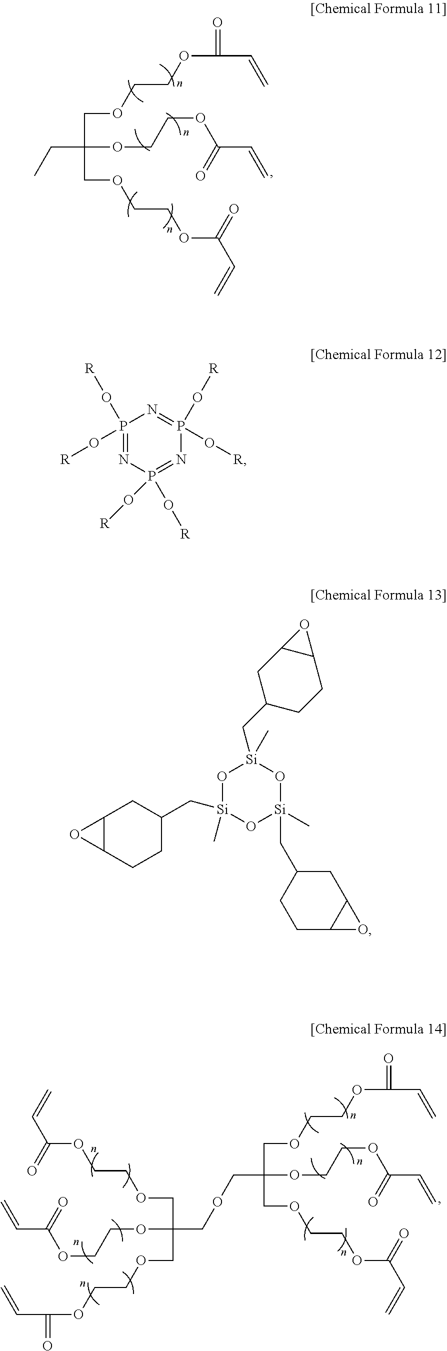

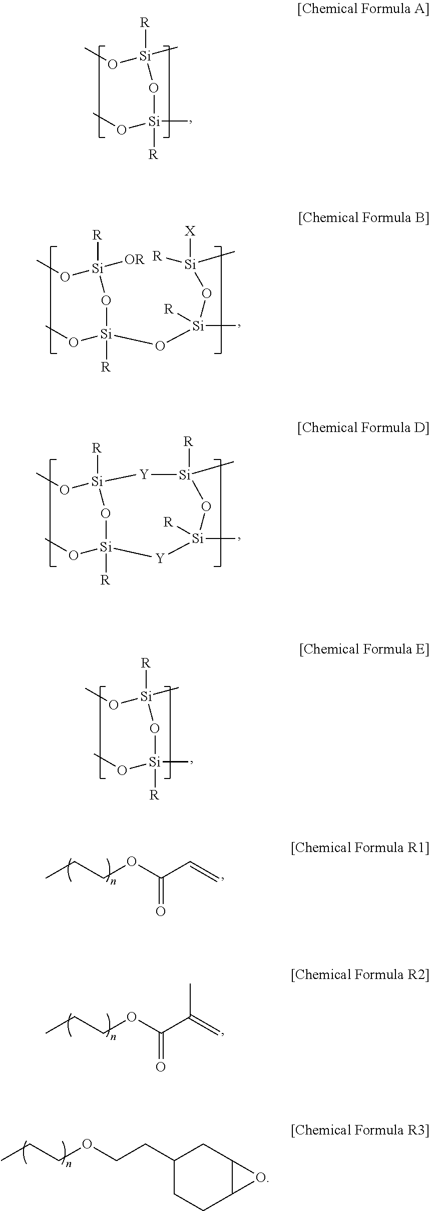

In Chemical Formulas 1 to 9, “A” may be expressed by Chemical Formula A, “B” may be expressed by Chemical Formula B, “D” may be expressed by Chemical Formula D, “E” may be expressed by Chemical Formula E, and “R” may be expressed by one of Chemical Formula R1, Chemical Formula R2, and Chemical Formula R3. In addition, each of “a1”, “a2”, “d1”, and “d2” may be independently defined in Chemical Formulas 1 to 9, and may be 1 or more, and may be equal to or different from each other. In addition, in Chemical Formulas R1, R2, and R3, n may be independently defined and may be 1 or more. In Chemical Formulas 10, 11, and 14, n may be independently defined and may be 1 or more.

In addition, “X” and “Y” are defined independently of each other, and are R′ or [(SiO3/2R′)4+2nR′]. Here, R′ may be each independently defined, and may be one selected from a group of an alkyl group (number of carbon atoms: 1 to 40); an alkenyl group (number of carbon atoms: 2 to 40); an alkoxy group (number of carbon atoms: 1 to 40); a cycloalkyl group (number of carbon atoms: to 40); a heterocycloalkyl group (number of carbon atoms: 3 to 40); an aryl group (number of carbon atoms: 6 to 40); a heteroaryl group (number of carbon atoms: 3 to 40); an aralkyl group (number of carbon atoms: 3 to 40); an aryloxy group (number of carbon atoms: to 40); and an arylthiol group (number of carbon atoms: 3 to 40), which is substituted or is not substituted with one or more of a group of hydrogen; deuterium; halogen element; an amine group; an epoxy group; a cyclohexyl epoxy group; a (meth)acrylic group; a thiol group; an isocyanate group; a nitrile group; a nitro group; a phenyl group; hydrogen, deuterium, halogen element, an amine group, an epoxy group, a cyclohexyl epoxy group, a (meth)acrylic group, a thiol group, an isocyanate group, a nitrile group, a nitro group, and a phenyl group.

According to an embodiment, the anti-reflection layer ARS may be disposed on the overcoat layer OC. In the display device DD according to an embodiment, the anti-reflection layer ARS configured to control external light reflectance may be formed at the outermost part of the display device DD. For example, the anti-reflection layer ARS may form a structure in which external lights dissipate and interfere with each other since a disposition relationship of layers is defined based on refractive indices of the layers. Accordingly, reflection of external light may be reduced and display quality may be effectively improved.

The anti-reflection layer ARS may be referred to as an “anti-reflection structure”.

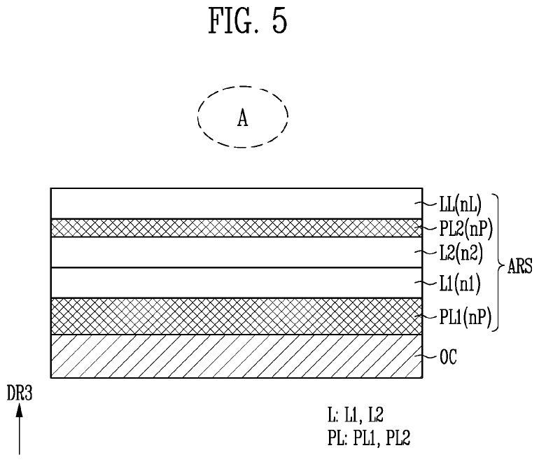

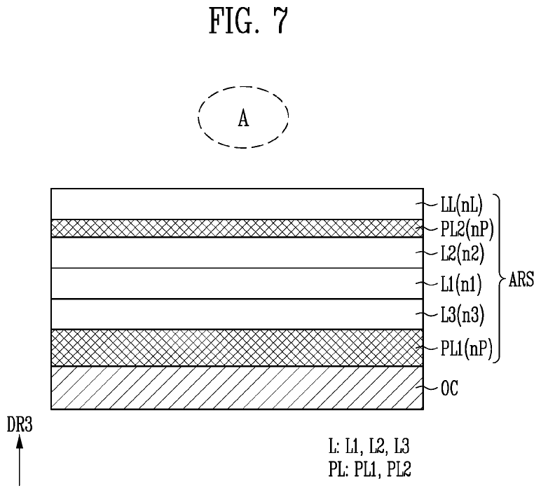

The anti-reflection layer ARS may include a plurality of layers that may be formed through a deposition process. For example, as process facilities used to manufacture the display device DD, a facility used to manufacture layers to be formed (for example, deposited) on the base layer BSL may be used to manufacture the anti-reflection layer ARS. In this case, since a separately manufactured film structure may not necessarily be required, a process cost may be reduced and process reliability may be improved. According to an embodiment, a layer disposed on the overcoat layer OC and the overcoat layer OC may be combined with each other without an adhesive layer therebetween. For example, the overcoat layer OC and a first passivation layer PL1 may be combined with each other without interposing an adhesive layer therebetween (FIGS. 5 and 7).

The anti-reflection layer ARS may be the outermost structure of the display device DD. The anti-reflection layer ARS may include a lower surface and an upper surface. The lower surface of the anti-reflection layer ARS may contact the overcoat layer OC. The upper surface of the anti-reflection layer ARS may be exposed. The anti-reflection layer ARS may be an external light reflection prevention structure, and may remove external light by controlling light information so that the light information emitted from the light emitting element LD is not distorted. According to an embodiment, since the anti-reflection layer ARS is formed at the outermost portion of the display device DD, reliability of an operation of controlling the light information may be secured.

In addition, since the anti-reflection layer ARS may be disposed over the entirety of the sub-pixel areas SPXA, a risk that a partial configuration (for example, the base layer BSL including a glass substrate) of the display device DD is damaged and thus other configurations are scattered may be effectively prevented.

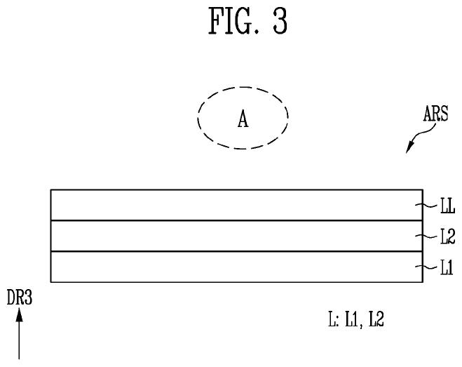

Hereinafter, a structure of the anti-reflection layer ARS according to an embodiment is described with reference to FIGS. 3 to 7.

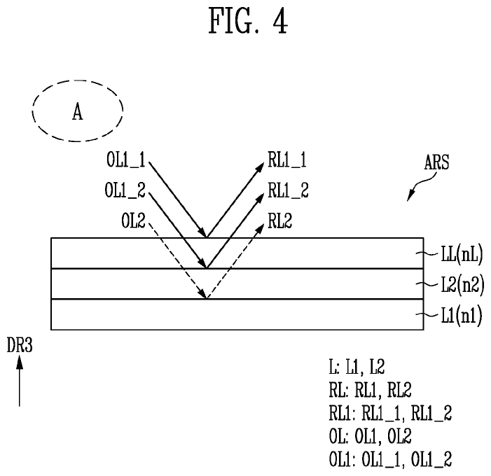

With reference to FIGS. 3 and 4, the anti-reflection layer ARS according to an embodiment is described. FIGS. 3 and 4 are schematic cross-sectional views illustrating the anti-reflection layer ARS according to an embodiment. FIG. 4 schematically shows an aspect in which external light is applied to the anti-reflection layer ARS according to an embodiment, and the applied external light is destructively interfered with each other and dissipates.

According to an embodiment, the anti-reflection layer ARS may include the refractive layer L and the outer refractive layer LL.

The refractive layer L may include a plurality of inorganic layers. For example, the refractive layer L may include a first refractive layer L1 and a second refractive layer L2.

The first refractive layer L1 may be adjacent to a lower side of the anti-reflection layer ARS, and the second refractive layer L2 may be disposed between the first refractive layer L1 and the outer refractive layer LL. The first refractive layer L1 and the second refractive layer L2 may physically contact each other and form an interface (i.e., border) therebetween.

The outer refractive layer LL may be disposed on the second refractive layer L2. According to an embodiment, the outer refractive layer LL may be the outermost layer among layers for implementing a display structure of the display device DD. For example, an upper surface of the outer refractive layer LL may be exposed. Accordingly, the anti-reflection layer ARS may form an outermost (for example, uppermost) structure of the display device DD.

Each of layers included in the refractive layer L may have one refractive index. For example, the first refractive layer L1 may have a first refractive index n1. The second refractive layer L2 may have a second refractive index n2. The outer refractive layer LL may have an outer refractive index nL.

According to an embodiment, a layer having the lowest refractive index in the anti-reflection layer ARS may be formed on the outermost portion of the anti-reflection layer ARS. According to an embodiment, a refractive index of each refractive layer L may be greater than the outer refractive index nL. For example, the first refractive index n1 may be greater than the outer refractive index nL. The second refractive index n2 may be greater than the outer refractive index nL.

According to an embodiment, the first refractive index n1 may be less than the second refractive index n2.

According to an embodiment, the first refractive layer L1 may include silicon oxynitride (SiOxNy). The first refractive index n1 may be in a range of 1.60 to 1.69. However, the disclosure is not necessarily limited thereto.

According to an embodiment, the second refractive layer L2 may include silicon nitride (SiNx). The second refractive index n2 may be in a range of 1.70 to 2.10. However, the disclosure is not necessarily limited thereto.

According to an embodiment, the outer refractive layer LL may include silica (SiOx) (for example, porous and hollow silica). According to an embodiment, the outer refractive layer LL may include one or more of a group of an organic material at least partially substituted with a fluorine group, an inorganic material at least partially substituted with a fluorine group, and an organic/inorganic hybrid material at least partially substituted with a fluorine group. The outer refractive index nL may be in a range of 1.23 to 1.40. However, the disclosure is not necessarily limited thereto.

Accordingly, the anti-reflection layer ARS may form a structure in which a low refractive index layer, a high refractive index layer, and a medium refractive index layer are sequentially disposed with respect to a direction in which external light is applied (e.g., a direction opposite to the third direction DR3).

According to an embodiment, when external light is applied to the display device DD, at least a portion of the external light and at least another portion of the external light may be destructively interfered with each other and may dissipate.

For example, external light OL may include first external light OL1 and second external light OL2. The first external light OL1 may be reflected at an interface (i.e., border) of at least some of the layers of the anti-reflection layer ARS and provided as first reflected light RL1. The second external light OL2 may be reflected at an interface (i.e., border) of at least some of the layers of the anti-reflection layer ARS and provided as second reflected light RL2.

The first external light OL1 may be light applied from an area having a relatively low refractive index to an area having a relatively high refractive index, and may be provided as the first reflected light RL1 after a phase is inverted (for example, changed by half a wavelength of the phase).

For example, the first external light OL1 may include (1_1)-th external light OL1_1 and (1_2)-th external light OL1_2. The first reflected light RL1 may include (1_1)-th reflected light RL1_1 and (1_2)-th reflected light RL1_2. The (1_1)-th external light OL1_1 may be reflected at an interface between an air layer A and the outer refractive layer LL and provided as the (1_1)-th reflected light RL1_1. The (1_1)-th reflected light RL1_1 may be light obtained by changing a phase of the (1_1)-th external light OL1_1 by half a wavelength of the (1_1)-th external light OL1_1. The (1_2)-th external light OL1_2 may be reflected at an interface between the outer refractive layer LL and the second refractive layer L2 and provided as the (1_2)-th reflected light RL1_2. The (1_2)-th reflected light RL1_2 may be light obtained by changing a phase of the (1_2)-th external light OL1_2 by half a wavelength of the (1_2)-th external light OL1_2.

The second external light OL2 may be light applied from an area having a relatively low refractive index to an area having a relatively high refractive index, a phase of second external light OL2 may be maintained (for example, the phase is not changed) after reflected, and the second external light OL2 may be provided as the second reflected light RL2.

For example, the second external light OL2 may be reflected at an interface (i.e., border) between the second refractive layer L2 and the first refractive layer L1 and provided as the second reflected light RL2.

Accordingly, a phase of a portion of light reflected to the outside from the anti-reflection layer ARS may be changed, and a phase of another portion of light reflected to the outside from the anti-reflection layer ARS may not be changed. That is, the first reflected light RL1 and the second reflected light RL2 may have phases opposite to each other (for example, different by half a wavelength in phase), and the first reflected light RL1 and the second reflected light RL2 may be destructively interfered with each other and may dissipate. As a result, a phase of a portion of the external light OL may be maintained, a phase of another portion of the external light OL may be inverted, and thus at least a portion of the external light OL may be removed. Accordingly, external light reflectance may be controlled, thereby implementing the display device DD having improved display quality and including an excellent color sense.

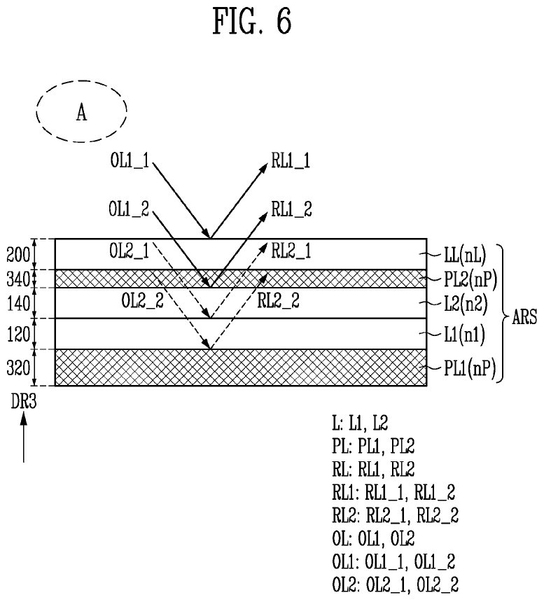

With reference to FIGS. 5 and 6, the anti-reflection layer ARS according to an embodiment is described. FIGS. 5 and 6 are schematic cross-sectional views illustrating the anti-reflection layer ARS according to an embodiment. FIG. 6 schematically illustrates an aspect in which external light is applied to the anti-reflection layer ARS according to an embodiment, and the applied external light is destructively interfered with each other and dissipates. For convenience of description, a content that may be overlap the above-described content is briefly described or is not repeated.

The anti-reflection layer ARS according to the present embodiment is different from the anti-reflection layer ARS of the embodiment described above, in that the anti-reflection layer ARS according to the present embodiment further includes a passivation layer PL.

According to an embodiment, the anti-reflection layer ARS may further include the passivation layer PL.

The passivation layer PL may be disposed on one surface of the refractive layer L, and may be directly adjacent to the refractive layer L according to an embodiment.

The passivation layer PL may include a first passivation layer PL1 and a second passivation layer PL2.

The first passivation layer PL1 may be disposed between the overcoat layer OC and the refractive layer L (for example, the first refractive layer L1). According to an embodiment, the first passivation layer PL1 may physically contact an upper surface of the overcoat layer OC. For example, one surface (e.g., lower surface) of the first passivation layer PL1 may contact the upper surface of the overcoat layer OC, and another surface of the first passivation layer PL1 may contact a lower surface of the first refractive layer L1.

The second passivation layer PL2 may be disposed between the outer refractive layer LL and the refractive layer L (for example, the second refractive layer L2). According to an embodiment, the second passivation layer PL2 may physically contact a lower surface of the outer refractive layer LL. For example, one surface (e.g., upper surface) of the second passivation layer PL2 may contact the lower surface of the outer refractive layer LL, and another surface (e.g., lower surface) of the second passivation layer PL2 may contact an upper surface of the second refractive layer L2.

The passivation layer PL may reduce a risk that the anti-reflection layer ARS is damaged from an external influence. For example, the passivation layer PL may be an anti-oxidation layer for the anti-reflection layer ARS.

For example, the passivation layer PL may include an oxide. For example, the passivation layer PL may include an oxide for an inorganic element the same as at least a portion of an inorganic material for forming the anti-reflection layer ARS. For example, the passivation layer PL may include silicon oxide (SiOx). However, the disclosure is not limited thereto.

According to an embodiment, the overcoat layer OC may include an organic material having a robust physical property, and structural stability of the anti-reflection layer ARS may be secured. Experimentally, when the anti-reflection layer ARS including an inorganic material is directly adjacent to an organic material, a risk that oxidation or the like of at least a portion of the anti-reflection layer ARS may occur due to moisture or the like passing through the organic material. In addition, the outer refractive layer LL may be formed at the outermost side of the display device DD, and thus an external factor may reduce reliability of an internal configuration of the anti-reflection layer ARS.

However, according to an embodiment, since the first passivation layer PL1 including oxide is patterned so as to be directly adjacent to the overcoat layer OC including an organic material, the risk that a refractive structure of the anti-reflection layer ARS is damaged may be reduced.

In addition, since the second passivation layer PL2 including oxide is patterned so as to be directly adjacent to the outer refractive layer LL, which is directly adjacent to an outer portion, a risk that the refractive structure of the anti-reflection layer ARS is damaged may be reduced.

As a result, as the passivation layer PL is selectively disposed in some areas of the anti-reflection layer ARS, a concern that a refractive structure is damaged from an external influence may be reduced, and reliability of display quality of the display device DD may be increased.

According to an embodiment, the passivation layer PL may have a passivation refractive index less than a refractive index of the refractive layer L. The passivation refractive index nP may be less than each of the first refractive index n1 and the second refractive index n2. For example, the passivation layer PL may include silicon oxide (SiOx), and the passivation refractive index nP may be in a range of 1.40 to 1.50.

In accordance with the anti-reflection layer ARS according to the present embodiment, a phase of a portion of light reflected to the outside from the anti-reflection layer ARS may be changed, a phase of another portion of light reflected to the outside from the anti-reflection layer ARS may not be changed, and these portions of the reflected lights may dissipate due to destructive interference with each other.

According to an embodiment, a second passivation thickness of the second passivation layer PL2 adjacent to the outer refractive layer LL may have a thickness less than a thickness of each of other layers, and at an interface defined at one surface (e.g., upper surface) of the second passivation layer PL2, light reflection may not substantially occur.

In addition, a first passivation thickness 320 of the first passivation layer PL1 disposed on a lower side of the anti-reflection layer ARS with respect to a direction in which external light is applied (i.e., a direction opposite to the third direction DR3) may have a thickness greater than a thickness of each of other layers, and at an interface defined at one surface (e.g., upper surface) of the first passivation layer PL1, light reflection may occur.

According to an embodiment, the first refractive layer L1 may have a first thickness 120. The second refractive layer L2 may have a second thickness 140. The outer refractive layer LL may have an outer thickness 200.

According to an embodiment, the first passivation thickness may be greater than each of the first thickness 120, the second thickness 140, and the second passivation thickness 340. The second passivation thickness 340 may be less than each of the first thickness and the second thickness 140. The outer thickness 200 may be substantially similar to (for example, identical to) each of the first thickness 120 and the second thickness 140.

For example, the first passivation thickness 320 may be in a range of 200 nm to 300 nm. The second passivation thickness 340 may be in a range of 20 nm to 50 nm. The first thickness 120 may be in a range of 50 nm to 150 nm. The second thickness 140 may be in a range of 50 nm to 150 nm. The outer thickness 200 may be in a range of 50 nm to 150 nm. However, the disclosure is not necessarily limited thereto.

According to an embodiment, the first external light OL1 may include the (1_1)-th external light OL1_1 and the (1_2)-th external light OL1_2. The first reflected light RL1 may include the (1_1)-th reflected light RL1_1 and the (1_2)-th reflected light RL1_2. The (1_1)-th external light OL1_1 may be reflected at the interface between the air layer A and the outer refractive layer LL and provided as the (1_1)-th reflected light RL1_1. The (1_1)-th reflected light RL1_1 may be light obtained by changing a phase of the (1_1)-th external light OL1_1 by half a wavelength of the (1_1)-th external light OL1_1. The (1_2)-th external light OL1_2 may be reflected at an interface between the second passivation layer PL2 and the second refractive layer L2 and provided as the (1_2)-th reflected light RL1_2. The (1_2)-th reflected light RL1_2 may be light obtained by changing a phase of the (1_2)-th external light OL1_2 by half a wavelength of the (1_2)-th external light OL1_2.

For example, the second external light OL2 may include a (2_1)-th external light OL2_1 and a (2_2)-th external light OL2_2. The second reflected light RL2 may include a (2_1)-th reflected light RL2_1 and a (2_2)-th reflected light RL2_2. The (2_1)-th external light OL2_1 may be reflected at an interface (i.e., border) between the first refractive layer L1 and the second refractive layer L2 and provided as the (2_1)-th reflected light RL2_1. The (2_1)-th reflected light RL2_1 may be light in which a phase of the (2_1)-th external light OL2_1 is maintained (for example, not changed). The (2_2)-th external light OL2_2 may be reflected at an interface between the first refractive layer L1 and the first passivation layer PL1 and provided as the (2_2)-th reflected light RL2_2. The (2_2)-th reflected light RL2_2 may be light in which a phase of the (2_2)-th external light OL2_2 is maintained (for example, not changed).

Accordingly, the first reflected light RL1 and the second reflected light RL2 may be destructively interfered with each other and may dissipate, and a risk due to external light reflection may be reduced.

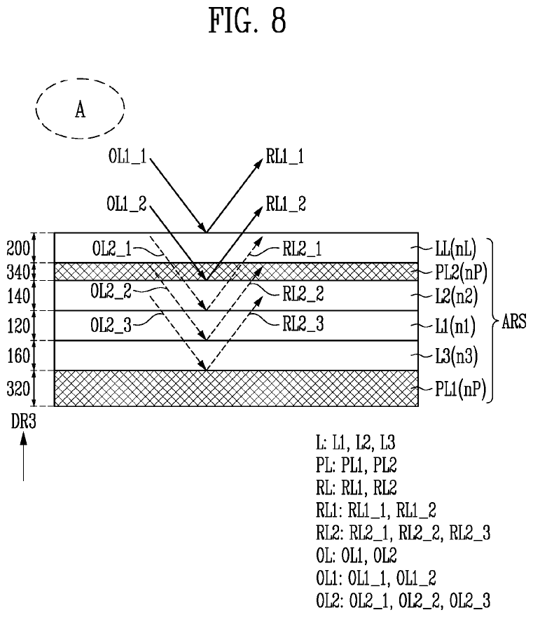

Referring to FIGS. 7 and 8, the anti-reflection layer ARS according to an embodiment is described. FIGS. 7 and 8 are schematic cross-sectional views illustrating the anti-reflection layer ARS according to an embodiment. FIG. 8 schematically shows an aspect in which external light is applied to the anti-reflection layer ARS according to an embodiment, and the applied external light is destructively interfered with each other and dissipates. For convenience of description, a content that may be overlap the above-described content is briefly described or is not repeated.

The anti-reflection layer ARS according to the present embodiment is different from the anti-reflection layer ARS of the embodiment described above, in that anti-reflection layer ARS according to the present embodiment includes a third refractive layer L3.

The third refractive layer L3 may be disposed between the first refractive layer L1 and the first passivation layer PL1. One surface (e.g., lower surface) of the third refractive layer L3 may be directly adjacent to (for example, in contact with) the first passivation layer PL1, and another surface (e.g., upper surface) of the third refractive layer L3 may be directly adjacent to (for example, in contact with) the first refractive layer L1.

The third refractive layer L3 may have a third refractive index n3. The third refractive index n3 may be greater than the passivation refractive index nP. The third refractive index n3 may be greater than the first refractive index n1. For example, the third refractive layer L3 may include silicon nitride (SiNx), and the third refractive index n3 may be in a range of 1.70 to 2.10. However, the disclosure is not necessarily limited thereto.

According to an embodiment, the third refractive layer L3 may include the same material as the second refractive layer L2. Accordingly, a refractive structure in which a high refractive index layer, a medium refractive index layer, and a high refractive index layer are sequentially stacked may be implemented between the first passivation layer PL1 and the second passivation layer PL2.

According to an embodiment, when the third refractive layer L3 is further included, as the first refractive layer L1 interposed between the second refractive layer L2 and the third refractive layer L3 has a relatively less refractive index, the above-described refractive structure may be implemented, and the first refractive layer L1 may include an oxide material capable of preventing a risk such as oxidation for other layers. In this case, the first refractive layer L1 may include silicon oxide (SiOx) identically to the passivation layer PL.

In accordance with the anti-reflection layer ARS according to the present embodiment, similarly, a phase of a portion of light reflected to the outside from the anti-reflection layer ARS may be changed, a phase of another portion of light reflected to the outside from the anti-reflection layer ARS may not be changed, and they may be destructively interfered with each other and may dissipate.

According to an embodiments, the first external light OL1 may include (1_1)-th external light OL1_1 and (1_2)-th external light OL1_2. The first reflected light RL1 may include (1_1)-th reflected light RL1_1 and (1_2)-th reflected light RL1_2. The (1_1)-th external light OL1_1 may be reflected at the interface between the air layer A and the outer refractive layer LL and provided as the (1_1)-th reflected light RL1_1. The (1_1)-th reflected light RL1_1 may be light obtained by changing a phase of the (1_1)-th external light OL1_1 by half a wavelength of the (1_1)-th external light OL1_1. The (1_2)-th external light OL1_2 may be reflected at an interface (i.e., border) between the second passivation layer PL2 and the second refractive layer L2 and provided as the (1_2)-th reflected light RL1_2. The (1_2)-th reflected light RL1_2 may be light obtained by changing a phase of the (1_2)-th external light OL1_2 by half a wavelength of the (1_2)-th external light OL1_2.

For example, the second external light OL2 may include a (2_1)-th external light OL2_1, a (2_2)-th external light OL2_2, and a (2_3)-th external light OL2_3. The second reflected light RL2 may include a (2_1)-th reflected light RL2_1, a (2_2)-th reflected light RL2_2, and a (2_3)-th reflected light RL2_3. The (2_1)-th external light OL2_1 may be reflected at the interface between the first refractive layer L1 and the second refractive layer L2 and provided as the (2_1)-th reflected light RL2_1. The (2_1)-th reflected light RL2_1 may be light in which a phase of the (2_1)-th external light OL2_1 is maintained (for example, not changed). The (2_2)-th external light OL2_2 may be reflected at an interface between the first refractive layer L1 and the third refractive layer L3 and provided as the (2_2)-th reflected light RL2_2. The (2_2)-th reflected light RL2_2 may be light in which a phase of the (2_2)-th external light OL2_2 is maintained (for example, not changed). The (2_3)-th external light OL23 may be reflected at an interface (i.e., border) between the third refractive layer L3 and the first passivation layer PL1 and provided as the (2_3)-th reflected light RL2_3. The (2_3)-th reflected light RL2_3 may be light in which a phase of the (2_3)-th external light OL2_3 is maintained (for example, not changed).

Accordingly, the first reflected light RL1 and the second reflected light RL2 may be destructively interfered with each other and may dissipate, and a risk due to external light reflection may be reduced.

As described above, although the disclosure has been described with reference to the preferred embodiment above, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims.

What is claimed is:

1. A display device comprising:
a display layer;
an overcoat layer disposed on the display layer and including an organic material; and
an anti-reflection layer disposed on the overcoat layer,
wherein the anti-reflection layer comprises:
a first passivation layer;
a first refractive layer disposed on the first passivation layer and having a first refractive index;
a second refractive layer disposed on the first refractive layer and having a second refractive index;
a second passivation layer disposed on the second refractive layer; and
an outer refractive layer disposed on the second passivation layer and having an outer refractive index,
wherein the first passivation layer and the second passivation layer include an oxide,
the first refractive index is less than the second refractive index, and
the outer refractive index is less than the first refractive index.

2. The display device according to claim 1, wherein a first surface of the first passivation layer contacts the overcoat layer, a second surface, opposite to the first surface, of the first passivation layer contacts the first refractive layer,
a first surface of the second passivation layer contacts the second refractive layer, and a second surface of the second passivation layer contacts the outer refractive layer.

3. The display device according to claim 1, wherein an outer surface of the outer refractive layer is exposed to an outside such that the outer refractive layer forms an outermost structure of the display device.

4. The display device according to claim 1, wherein the first refractive layer includes silicon oxynitride (SiOxNy), and
the second refractive layer includes silicon nitride (SiNx).

5. The display device according to claim 1, wherein the outer refractive layer includes one or more among silica, an organic material at least partially substituted with a fluorine group, an inorganic material at least partially substituted with a fluorine group, and an organic/inorganic hybrid material at least partially substituted with a fluorine group.

6. The display device according to claim 1, wherein the first passivation layer and the second passivation layer include silicon oxide (SiOx).

7. The display device according to claim 1, wherein the first refractive index is in a range of 1.60 to 1.69,
the second refractive index is in a range of 1.70 to 2.10, and
the outer refractive index is in a range of 1.23 to 1.40.

8. The display device according to claim 1, wherein a thickness of the second passivation is less than a thickness of each of the first refractive layer, the second refractive layer, the first passivation layer, and the outer refractive layer.

9. The display device according to claim 8, wherein the first refractive layer has the thickness in a range of 50 nanometers (nm) to nm,
the second refractive layer has the thickness in a range of 50 nm to 150 nm,
the first passivation layer has the thickness in a range of from 200 nm to 300 nm,
the outer refractive layer has the thickness in a range of 50 nm to 150 nm, and
the second passivation layer has the thickness in a range of 20 nm to 50 nm.

10. The display device according to claim 1, wherein when external light is applied to the display device,
at least a portion of the external light is reflected at an outer surface of the outer refractive layer or at an interface between the second passivation layer and the second refractive layer, and is provided as first reflected light of which a phase is inverted with respect to a phase of the at least a portion of the external light, and
at least another portion of the external light is reflected at an interface between the first refractive layer and the second refractive layer or at an interface between the first passivation layer and the first refractive layer and is provided as second reflected light of which a phase is maintained with respect to a phase of the at least another portion of the external light.

11. The display device according to claim 10, wherein at least a portion of the first reflected light and at least a portion of the second reflected light dissipate by destructive interference with each other.

12. The display device according to claim 1, further comprising:
a plurality of sub-pixels forming sub-pixel areas, respectively,
wherein the anti-reflection layer includes an inorganic material disposed over the sub-pixel areas.

13. The display device according to claim 1, wherein the overcoat layer and the first passivation layer are combined with each other without an adhesive layer interposed therebetween.

14. The display device according to claim 1, further comprising:
a color conversion layer disposed on the display layer and including a quantum-dot; and
a color filter layer disposed on the color conversion layer and configured to selectively transmit light of one color.

15. The display device according to claim 1, wherein the display layer includes an organic light emitting diode (OLED).

16. The display device according to claim 1, wherein the overcoat layer forms a base on which the anti-reflection layer is disposed.

17. The display device according to claim 16, wherein the overcoat layer has a thickness in a range of 3 micrometers (μm) to 10 μm.

18. A display device comprising:
a display layer;
an overcoat layer disposed on the display layer and including an organic material; and
an anti-reflection layer disposed on the overcoat layer,
wherein the anti-reflection layer comprises:
a first passivation layer;
a third refractive layer disposed on the first passivation layer and having a third refractive index;
a first refractive layer disposed on the third refractive layer and having a first refractive index;
a second refractive layer disposed on the first refractive layer and having a second refractive index;
a second passivation layer disposed on the second refractive layer; and
an outer refractive layer disposed on the second passivation layer and having an outer refractive index,
wherein the first passivation layer, the second passivation layer, and the first refractive layer include an oxide,
the second refractive layer and the third refractive layer include the same material,
the second refractive index and the third refractive index each are greater than the first refractive index, and
the outer refractive index is less than the first refractive index.

19. The display device according to claim 18, wherein the first passivation layer and the second passivation layer include silicon oxide (SiOx),
the first refractive layer includes silicon oxide (SiOx), and
the second refractive layer and the third refractive layer include silicon nitride (SiNx).

20. The display device according to claim 18, wherein the first refractive index is in a range of 1.60 to 1.69, and
the second refractive index and the third refractive index each are in a range of 1.70 to 2.10.
